(19) United States
(12) Patent Application Publication
(10) Pub. No.: US 2007/0108063 A1
(43) Pub. Date: May 17, 2007

(54) Layer forming method, layer forming apparatus, workpiece processing apparatus, interconnect forming method, and substrate interconnect structure

(75) Inventors: Tsutomu Nakada, Ohta-ku (JP); Makoto Kubota, Ohta-ku (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: EBARA CORPORATION, Ohta-ku (JP)

(21) Appl. No.: 11/525,813

(22) Filed: Sep. 25, 2006

(30) Foreign Application Priority Data
Sep. 28, 2005 (JP) 2005-282910

(51) Int. Cl. C23C 16/00; B05D 3/02; B32B 3/00

(52) U.S. Cl. 205/510; 427/248.1; 427/314; 428/209; 257/508

(57) ABSTRACT

The present invention provides a layer forming apparatus including a material vaporizing section 108 for producing a material gas containing a metal-organic material by heating and vaporizing the metal-organic material in a solid or liquid state under pressure ranging from 0.01 Pa to atmospheric pressure, a workpiece holding section 100 for holding a workpiece, a workpiece heating section 104 for heating a surface of the workpiece to a temperature higher than a decomposition temperature of the metal-organic material vaporized by the material vaporizing section, and a material supply section 109 for locally forming an atmosphere of the material gas on the surface of the workpiece. The material supply section 109 is operable to form a metal layer or a metal compound layer on the surface of the workpiece by exposing at least a portion of the surface of the workpiece to the atmosphere of the material gas.

### BACKGROUND OF THE INVENTION

1. Field of the Invention

The present invention relates to layer forming method and apparatus, and more particularly to layer forming method and apparatus for forming a metal layer or a metal compound layer on a surface of a workpiece for use in a semiconductor device, a flat panel display, a micro electro mechanical system (MEMS), a precision electronic device, and the like. The present invention also relates to a workpiece processing apparatus, and more particularly to a workpiece processing apparatus having a wet or dry processing unit operable to bring a processing liquid (e.g., a chemical liquid or pure water) or a gas into contact with a surface of a workpiece or operable to heat-treat the workpiece. Further, the present invention relates to an interconnect forming method, and more particularly to a semiconductor fine interconnect forming method for forming copper interconnects using electroplating on a barrier metal layer formed on a surface of a substrate. Furthermore, the present invention relates to a substrate interconnect structure produced by such an interconnect forming method.

2. Description of the Related Art

As a copper-interconnect forming technique for 45-nm node, there has been proposed a process of forming a copper film directly onto a surface of a barrier metal using electroplating. Possible materials to be used for such a barrier metal include Ru and Os, and such a barrier metal is formed using a chemical vapor deposition (CVD), an atomic layer deposition (ALD), a physical vapor deposition (PVD), or the like. Particularly, a process of forming a thin film of metal or metal compound using CVD is regarded as a key technique that can be an alternative to a sputtering method because of its superiority of step coverage of a workpiece (see a non-patent document 1 below, for example).

In a typical CVD apparatus, a material gas is introduced into a chamber from outside through a port provided on the chamber and is simultaneously discharged to thereby form a flow of the material gas in the chamber. With this structure, a large amount of material gas is required for forming a layer. Further, such a flow of the gas would be disturbed by a shape of the chamber, components installed in the chamber, and consumption of the material gas due to chemical reaction, causing non-uniform film formation.

In order to suppress turbulence of the gas flow, a rectifier may be installed in the chamber. However, in this case, a volume of the chamber becomes very large compared with the size of the workpiece. Further, since an atmosphere in the chamber is controlled by a replacement operation of the gas in the entire chamber, a large gas-evacuation system is required for replacement of the gas in a case of using a large chamber. Accordingly, it is difficult to combine the CVD apparatus as a layer-forming unit with a wet processing apparatus, such as a plating apparatus, or with a dry processing apparatus, such as an annealing apparatus.

Furthermore, in a fine copper interconnect structure produced by the above process, there is a need to enhance reliability against copper diffusion and to improve adhesion to copper.

[Non-patent document 1] “Applied physical engineering selected works 3, Thin film”, Sadafumi Yoshida, Baifukan, 1990, pages 64-70.

### SUMMARY OF THE INVENTION

The present invention has been made in view of the above drawbacks. It is therefore a first object of the present invention to provide a layer forming method and a layer forming apparatus which can secure good step coverage and do not need both a large gas-evacuation system and a large chamber as compared with a workpiece.

It is a second object of the present invention to provide a workpiece processing apparatus which can perform both a layer forming process and a wet or dry process.

Further, it is a third object of the present invention to provide a substrate interconnect structure and an interconnect forming method which have enhanced reliability against copper diffusion and improved adhesion to copper.

In order to achieve the above objects, one aspect of the present invention provides a layer forming method comprising heating a surface of a workpiece, producing a material gas containing a metal-organic material by heating and vaporizing the metal-organic material in a solid or liquid state under pressure ranging from 0.01 Pa to atmospheric pressure, locally forming an atmosphere of the material gas on the surface of the workpiece, and forming a metal layer or a metal compound layer on the surface of the workpiece by exposing at least a portion of the surface of the workpiece to the atmosphere of the material gas.

A metal-organic material in the form of block, grain, or powder can be used as the solid metal-organic material. Examples of the liquid metal-organic material include a solution in which a metal-organic material is dissolved in a solvent, such as water, i.e., a metal-organic material solution. That is, any material can be used in the layer forming method and apparatus according to the present invention so long as the material contains a metal-organic material in a solid or liquid state under pressure ranging from 0.01 Pa to atmospheric pressure.

Examples of the above material gas include, other than the vaporized metal-organic material, a mixture of a gaseous metal-organic material and an inert gas (carrier gas) such as N₂ gas, and an aerosol of a powdery metal-organic material.

According to the present invention, because the atmosphere of the material gas is locally formed on the surface of the workpiece, it is not necessary to supply the material gas into the chamber in its entirety. Accordingly, an amount of the metal-organic material used can be greatly reduced. Further, because the volume of the chamber can be small, the entire apparatus can be compact. As a result, the apparatus can be combined with a wet or dry processing apparatus.

In a preferred aspect of the present invention, the layer forming method further comprises supplying the material gas through a supply port onto a portion of the surface of the workpiece facing the supply port, and moving the supply port and the workpiece relative to one another with a distance between the supply port and the workpiece being kept constant to thereby locally form the atmosphere of the material gas on the surface of the workpiece, wherein the supply port has an area equal to or smaller than that of the surface of the workpiece.

In a preferred aspect of the present invention, the layer forming method further comprises providing a unit having a material vaporizing section for vaporizing the metal-organic material and the supply port which are integrally combined. Moving the supply port and the workpiece comprises moving the unit and the workpiece relative to one another.

In a preferred aspect of the present invention, wherein the distance from the supply port to the surface of the workpiece is not more than six times a minimal width of the supply port.

In order to secure good step coverage for the workpiece, it is essential to perform a layer forming process in a region where surface reaction is rate-limiting (see “Research report on wiring materials for high integration device (II)”, Nobuyoshi Awaya, Japan Electronic Industry Development Association, 1996, page 187, for example). However, the gas flow is disturbed by a shape of the chamber, components installed in the chamber, and consumption of the material gas due to chemical reaction of the metal-organic material. Accordingly, a concentration (partial pressure) distribution of the metal-organic material is created in the chamber, and this concentration distribution would also be created on the workpiece. As a result, supply (transit) becomes rate-limiting on a portion of the surface of the workpiece where a concentration of the metal-organic material is low, and hence a uniform film-thickness and good step coverage cannot be obtained.

FIG. 1 is a schematic view showing a two-dimensional free jet model of a jet J ejected through an ejection port E having a width of “a”. As shown in FIG. 1, the jet J is violently mixed with a surrounding fluid to create turbulence, and the jet J itself becomes wider. Around the ejection port E, the turbulence gradually permeates from outside toward a center line X of the jet J as the jet J travels away from the ejection port E. As a result, a wedge-shaped region (i.e., a potential core) P where an average velocity of the jet J is not decreased at all is created. The length of the potential core P, extending along the center line X of the jet J, is six times the width “a” of the ejection port E, i.e., the length of the potential core P is “6a”. A region around the potential core P is called a mixing zone.

This explanation can be applied not only to a case where the ejection port E has a circular shape having a diameter “a” as shown in FIG. 2A, but also to a case where the ejection port E has a rectangular shape having a short side “a” and a long side “b” as shown in FIG. 2B. A graph in FIG. 3 shows a relationship between uₘ₀/U₀ and x/a with several variations of b/a, where “U₀” is a uniform velocity of the jet J, “uₘ₀” is a velocity of the jet J on the center line X, and “x” is a distance from the ejection port E along the center line X (see “Turbulent jet” on page 1,268, Author; N. Rajaratnam, Translator; Yasumasa Nomura, Publisher; Morikita Publishing Co., Ltd, 1981). As can be seen from FIG. 3, the length of the potential core (a region where an equation “uₘ₀/U₀=1.00” holds) is 6a, regardless of a value of b/a.

In view of the above, the distance from the ejection port to the surface of the workpiece is set to be not more than six times the minimal width of the ejection port when the vaporized metal-organic material is ejected through the ejection port, so that the surface of the workpiece is positioned within the potential core. With this arrangement, the gas flow with a uniform velocity can be supplied onto the surface of the workpiece without the ejection velocity being lowered. Accordingly, a concentration of the metal-organic material on the surface of the workpiece is kept constant without being decreased from a concentration of the metal-organic material at the ejection port. As a result, the layer can be formed under the condition that reaction is rate-limiting, without causing the condition that supply is rate-limiting. Hence, a layer with a uniform thickness and good step coverage can be obtained. Under this condition, the metal-organic material being supplied to the surface of the workpiece is a fluid in a viscous flow region.

In a preferred aspect of the present invention, the layer forming method further comprises providing a heater adjacent to the supply port at a rear of the supply port with respect to a moving direction of the supply port, annealing the layer by the heater simultaneously with the forming the layer, and repeating the forming the layer and the annealing at least two times.

Generally, a metal layer or a metal compound layer of the metal-organic material is formed by chemical reaction of the metal-organic material, which is inevitably accompanied by decomposition products including hydrocarbon and carbon. These decomposition products are entrapped in the layer during deposition of the layer, and are also attached to the surface of the workpiece, causing contamination of the surface of the workpiece. As a result, a quality of the layer would be deteriorated, and adhesion of the layer to the workpiece would be lowered. Further, adhesion of the layer also depends on an inherent character of materials, i.e., the ease with which electron cloud of a material constituting the layer and electron cloud of a material constituting the workpiece overlap.

In order to prevent deterioration of the layer quality and lowering of the adhesion of the layer to the workpiece, it is necessary to anneal the layer using a heater. An infrared lamp furnace capable of controlling its output and a heating time, a laser capable of controlling its output and a heating time and capable of locally heating the layer, or the like can be used as the heater.

By performing such an annealing process using the heater, the decomposition products, which have been entrapped in the layer, diffuse to the surface of the layer and are expelled to the outside of the layer, whereby the layer quality is improved. In addition, the annealing process causes thermal vibration to atomic lattices constituting the layer and the workpiece: As a result, regardless of whether the decomposition products exist between the layer and the workpiece, the layer and the workpiece come close together sufficiently and are thus joined to each other. Furthermore, interdiffusion and replacement of atoms between the layer and the workpiece occur at the interface thereof, resulting in strong adhesion therebetween.

On the other hand, if an excess thermal energy is applied to the layer during the annealing process, surface diffusion is promoted, and a surface energy of the layer itself causes condensation of the layer. The progress of such condensation would cause a non-uniform thickness of the layer and separation of the layer. For this reason, the present invention includes first forming a layer having a smaller thickness than a desired thickness, rather than forming a layer having the desired thickness at a time, and then annealing the thin layer by the heater adjacent to the ejection port. Because the layer to be annealed is thin, an absolute magnitude of atom migration upon surface diffusion of the layer is restricted, and hence the progress of the layer condensation is suppressed. In addition thereto, a time required for expelling the decomposition products to the outside of the layer can be shortened. Accordingly, the resulting layer can have a high quality and good adhesion. Furthermore, in this layer forming method, the layer forming process and the annealing process are repeated so as to laminate the thin layers each having a high quality and good adhesion. As a result, a layer having a desired thickness, a high quality, and good adhesion can be finally formed on the workpiece.

In the range of 0.01 MPa to the atmospheric pressure, the metal-organic material to be supplied to the surface of the workpiece is a fluid in a viscous flow region. In this viscous flow region, a thermal conductivity of the atmosphere is higher than that in a molecular flow region. Therefore, heat removal of the layer after annealing is rapidly performed.

In a preferred aspect of the present invention, the layer forming method further comprises providing an impregnation member so as to face the workpiece, and impregnating the impregnation member with the metal-organic material in a liquid state. The metal-organic material retained by the impregnation member is heated and vaporized to thereby produce the material gas containing the metal-organic material.

In a preferred aspect of the present invention, the impregnation member comprises at least one of a porous material, a nonwoven fabric, and a woven fabric.

In a preferred aspect of the present invention, a distance from a surface of the impregnation member to the surface of the workpiece is set to be not more than 10 mm.

In a preferred aspect of the present invention, the layer forming method further comprises preparing a workpiece having a space therein, supplying the material gas into the space to thereby perform the locally forming the atmosphere of the material gas on the surface of the workpiece, and discharging the material gas and decomposition products thereof from the space.

In a preferred aspect of the present invention, the supplying and the discharging are performed using two passages which are concentrically arranged.

In a preferred aspect of the present invention, producing of the material gas comprises coating a material supply member with the metal-organic material to form a coating film of the metal-organic material, locating the material supply member so as to face the workpiece, and heating the coating film of the metal-organic material on the material supply member to thereby vaporize the metal-organic material. A distance between the workpiece and the material supply member is not more than 3 mm.

In a preferred aspect of the present invention, heating of the coating film of the metal-organic material on the material supply member is performed by convection heat or radiant heat from the surface of the workpiece heated.

In a preferred aspect of the present invention, the metal-organic material contains at least one of cobalt, tungsten, platinum, aluminum, copper, molybdenum, manganese, and silicon.

In a preferred aspect of the present invention, the workpiece is a semiconductor wafer, a ceramic, a resin, or a metal.

In a preferred aspect of the present invention, the workpiece has thereon at least one layer composed of a material selected from the group consisting of semiconductor, ceramic, resin, Ru, RuO₂, Cu, Ta, TaN, Ti, TiN, Si, SiO₂, low-k material, Co, P CoP, CoWP, W, WSiC, WC, Ni, and Al.

Another aspect of the present invention is to provide an interconnect forming method comprising forming a barrier metal layer on a surface of a workpiece having an interconnect trench, forming a metal layer or a metal compound layer on the barrier metal layer using the above layer forming method, performing electroplating using the metal layer or the metal compound layer as a seed layer to thereby fill the interconnect trench with a copper, and removing part of the copper by chemical mechanical polishing.

In a preferred aspect of the present invention, the metal layer or the metal compound layer is a metal layer composed mainly of cobalt.

In a preferred aspect of the present invention, the interconnect forming method further comprises performing electroless plating to selectively form a metal layer composed mainly of cobalt on a surface of the copper filling the interconnect trench.

Another aspect of the present invention is to provide a substrate interconnect structure comprising a copper filling an interconnect trench, a barrier metal layer, a metal layer composed mainly of cobalt and formed between the copper and the barrier metal layer, and a metal layer composed mainly of cobalt and formed on an exposed surface of the copper. The metal layer formed between the copper and the barrier metal layer is a cobalt layer formed by the above layer forming method. The metal layer on the exposed surface of the copper is formed by electroless plating.

Another aspect of the present invention is to provide a layer forming apparatus comprising a material vaporizing section for producing a material gas containing a metal-organic material by heating and vaporizing the metal-organic material in a solid or liquid state under pressure ranging from 0.01 Pa to atmospheric pressure, a workpiece holding section for holding a workpiece, a workpiece heating section for heating a surface of the workpiece to a temperature higher than a decomposition temperature of the metal-organic material vaporized by the material vaporizing section, and a material supply section for locally forming an atmosphere of the material gas on the surface of the workpiece. The material supply section is operable to form a metal layer or a metal compound layer on the surface of the workpiece by exposing at least a portion of the surface of the workpiece to the atmosphere of the material gas.

In a preferred aspect of the present invention, the layer forming apparatus further comprises a supply port for supplying the material gas onto a portion of the surface of the workpiece, and a moving mechanism for moving the supply port and the workpiece, which faces the supply port, relative to one another with a distance between the supply port and the workpiece being kept constant. The supply port has an area equal to or smaller than that of the surface of the workpiece.

In a preferred aspect of the present invention, the material vaporizing section and the material supply section are integrated into a unit; and the moving mechanism is operable to provide relative movement between the unit and the workpiece.

In a preferred aspect of the present invention, the distance from said supply port to the surface of the workpiece is not more than six times a minimal width of said supply port.

In a preferred aspect of the present invention, the layer forming apparatus further comprises a heater provided adjacent to the supply port at a rear of the supply port with respect to a moving direction of the supply port.

In a preferred aspect of the present invention, the material supply section includes an impregnation member disposed so as to face the workpiece; and the impregnation member is impregnated with the metal-organic material in a liquid state.

In a preferred aspect of the present invention, the impregnation member comprises at least one of a porous material, a nonwoven fabric, and a woven fabric.

In a preferred aspect of the present invention, a distance from a surface of the impregnation member to the surface of the workpiece is not more than 10 mm.

In a preferred aspect of the present invention, the material supply section has a material supply passage for supplying the material gas into a space formed in the workpiece. The material supply passage is coupled to the space via a seal member. The material supply section further has a material discharge passage for discharging the material gas and decomposition products thereof from the space. The material discharge passage is coupled to the space via a seal member.

In a preferred aspect of the present invention, the material supply section and the material discharge passage are provided as two passages which are concentrically arranged.

In a preferred aspect of the present invention, the material supply section comprises a material supply member having a coating film of the metal-organic material thereon, the material supply member faces the workpiece, and a distance between the workpiece and the material supply member is not more than 3 mm.

In a preferred aspect of the present invention, the coating film of the metal-organic material on the material supply member is heated and vaporized by convection heat or radiant heat from the surface of the workpiece heated.

Another aspect of the present invention is to provide a workpiece processing apparatus comprising the above layer forming apparatus, and a wet processing unit for performing a wet process on a workpiece having a metal layer or a metal compound layer formed by the layer forming apparatus.

In a preferred aspect of the present invention, the wet processing unit comprises at least one of an electroplating unit, an electroless plating unit, a chemical mechanical polishing unit, an electrolytic etching unit, an electrolytic polishing unit, and a cleaning unit.

Another aspect of the present invention is to provide a workpiece processing apparatus comprising the above layer forming apparatus, and a dry processing unit for performing a dry process on a workpiece having a metal layer or a metal compound layer formed by the layer forming apparatus.

In a preferred aspect of the present invention, the dry processing unit comprises at least one of an annealing unit, a CVD unit, and a gas etching unit.

### BRIEF DESCRIPTION OF THE DRAWINGS

FIG. 1 is a schematic view showing a two-dimensional free jet model of a jet ejected through an ejection port;

FIGS. 2A and 2B are views each showing an example of a shape of the ejection port shown in FIG. 1;

FIG. 3 is a graph showing velocity attenuation of the jet ejected through the ejection port having a rectangular shape;

FIG. 4 is a schematic view showing a layer forming apparatus according to an embodiment of the present invention;

FIG. 5 is a schematic view showing a layer forming apparatus according to another embodiment of the present invention;

FIG. 6 is a schematic view of the embodiment as viewed from a direction indicated by arrow VI in FIG. 5;

FIG. 7 is a schematic view showing a layer forming apparatus according to another embodiment of the present invention;

FIG. 8 is a schematic view of the embodiment as viewed from a direction indicated by arrow VIII in FIG. 7;

FIG. 9 is a schematic view showing a layer forming apparatus according to another embodiment of the present invention;

FIG. 10 is a schematic view showing a layer forming apparatus according to another embodiment of the present invention;

FIG. 11 is a schematic view showing a layer forming apparatus according to another embodiment of the present invention;

FIG. 12 is a schematic view showing another example of the embodiment;

FIG. 13 is a schematic view showing a layer forming apparatus according to another embodiment of the present invention;

FIG. 14 is a schematic view showing a layer forming apparatus according to another embodiment of the present invention;

FIG. 15 is a plan view showing a workpiece processing apparatus having a layer forming apparatus (layer forming unit) according to the present invention;

FIG. 16 is a schematic view showing the layer forming unit shown in FIG. 15;

FIG. 17 is a schematic view showing an electroplating unit shown in FIG. 15;

FIGS. 18A through 18C are views showing processes using the workpiece processing apparatus shown in FIG. 15; and

FIGS. 19A and 19B are views showing processes using the workpiece processing apparatus shown in FIG. 15.

### DETAILED DESCRIPTION OF THE PREFERRED EMBODIMENTS

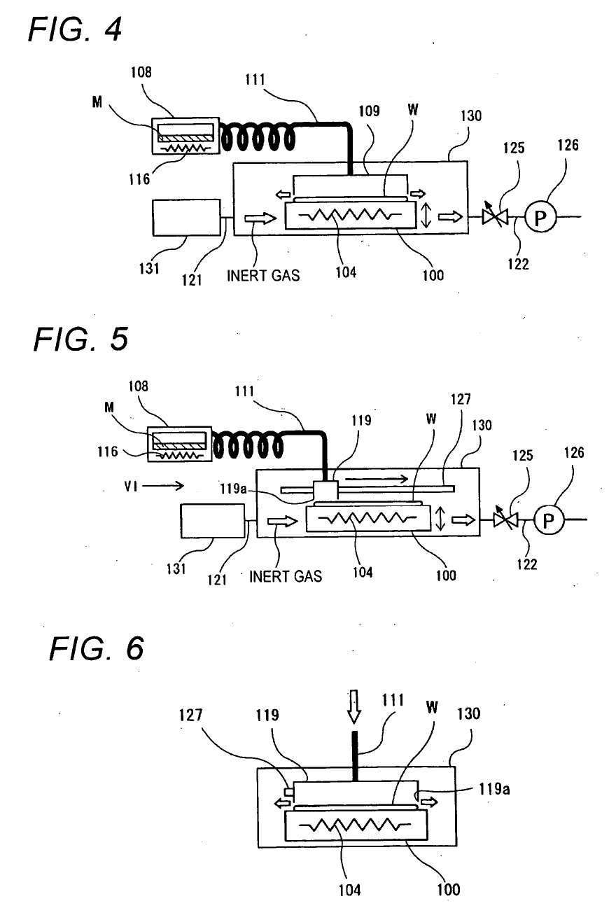

Embodiments of the present invention will be described below in detail with reference to FIG. 4 through FIG. 19B. In FIG. 4 through FIG. 19B, the same or similar components will be denoted by the same reference numerals, and will not be described repetitively.

FIG. 4 is a schematic view showing a layer forming apparatus according to an embodiment of the present invention. This layer forming apparatus is operated so as to heat and vaporize a solid or liquid metal-organic material to produce a material gas containing the metal-organic material, locally form an atmosphere of the material gas on a surface of a workpiece, and expose the surface of the heated workpiece to the atmosphere to thereby form a metal layer or a metal compound layer on the surface of the workpiece.

As shown in FIG. 4, the layer forming apparatus comprises a workpiece holding section (susceptor) 100 for holding a workpiece W with its surface facing upwardly, a material vaporizing section 108 for heating and vaporizing a metal-organic material M to produce a material gas containing the metal-organic material M, and a material supply section 109 coupled to the material vaporizing section 108 for supplying the material gas onto the workpiece W.

The workpiece holding section 100 has a vacuum chuck mechanism (not shown in the drawings) on an upper surface thereof, so that the workpiece W is held on the upper surface of the workpiece holding section 100 by the vacuum chuck mechanism. Instead of the vacuum chuck mechanism, an electrostatic chuck mechanism for holding the workpiece W via an electrostatic force may be used. The workpiece holding section 100 is vertically movable, so that the workpiece holding section 100 is lowered to receive and release the workpiece W and is elevated to perform layer formation. Inside the workpiece holding section 100, a first heater (a workpiece heating section) 104 is embedded for heating the workpiece W attracted by the vacuum chuck mechanism to the upper surface of the workpiece holding section 100. By supplying an electric current to the heater 104, the workpiece W is heated to a temperature (e.g., 150° C.) higher than the decomposition temperature of the metal-organic material M. The temperature of the workpiece W is changed according to the metal-organic material used.

The chamber 130 is connected to a gas-introduction pipe 121 for introducing an inert gas (e.g., nitrogen or argon) from an inert gas supply source 131 into the chamber 130. The chamber 130 is further connected to a gas-discharge pipe 122 for discharging the inert gas from the chamber 130. The gas-discharge pipe 122 is coupled to a vacuum pump 126 via a flow rate adjustment valve 125. Pressure in the chamber 130 is set to be, for example, atmospheric pressure by adjusting a flow rate of the inert gas from the inert gas supply source 131 and the flow rate adjustment valve 125.

In this layer forming apparatus, the metal-organic material M is selected from metal-organic materials in a solid or liquid state under pressure ranging from 0.01 Pa to atmospheric pressure. Preferred examples of the metal-organic material M include organic metal (e.g., organic cobalt (Co), organic tungsten (W), organic platinum (Pt), organic aluminum (Al), organic copper (Cu), organic molybdenum (Mo), organic manganese (Mn)), or organic silicon (Si), or hydrocarbon, or a combination thereof. For example, a material in which alkyl, phenyl, pentadienyl, or carbonyl coordinates to metal or semiconductor can be used as the metal-organic material M. It is preferable that the decomposition temperature of the metal-organic material M is significantly higher than a temperature at which the metal-organic material M can be vaporized.

The material vaporizing section 108 has a heater (a second heater) 116 for heating the metal-organic material M. This material vaporizing section 108 vaporizes the metal-organic material M by heating the metal-organic material M using the heater 116 to thereby produce a material gas containing the metal-organic material M. For example, the metal-organic material M is heated by the heater 116 to a temperature of 70° C. During heating, the inert gas may be introduced into the material vaporizing section 108 so as to carry the vaporized metal-organic material M to the workpiece W. In this manner, the material vaporizing section 108 produces the material gas, such as the vaporized metal-organic material M, or a mixture of the inert gas and the gaseous metal-organic material M, or an aerosol of a powdery metal-organic material M.

The material vaporizing section 108 communicates with the material supply section 109 through a communication pipe 111 which is configured to freely expand and contract. The material supply section 109 is arranged so as to face the surface of the workpiece W when held by the workpiece holding section 100. Further, this material supply section 109 has substantially the same circumferential dimension(s) as that of the workpiece W, and is shaped like a shroud covering the surface of the workpiece W in its entirety. The material gas, produced in the material vaporizing section 108, is delivered through the communication pipe 111 to the surface of the workpiece W and stays in the material supply section 109 to thereby produce a local atmosphere of the material gas on the surface of the workpiece W. A gap is formed between the material supply section 109 and the workpiece W, so that an excess difference in pressure between the inside and the outside of the material supply section 109 can be eliminated.

The surface of the workpiece W is exposed to the local atmosphere of the material gas formed in the material supply section 109, and simultaneously the surface of the workpiece W is heated by the heater 104. As a result, the metal-organic material is pyrolyzed, and a metal layer or a metal compound layer is deposited on the surface of the workpiece W.

Depending on the kind of metal-organic material, a metal oxide is produced as a result of thermal decomposition. For this reason, the layers to be formed by this embodiment of the present invention include not only the metal layer, but also the metal compound layer.

During the layer formation process, the inert gas is kept flowing through the chamber 130 at all times. This flow of the inert gas can successively replace the material gas, which has supplied through the material supply section 109, with a new material gas, and can keep the temperature in the chamber 130 substantially constant. Further, supply of the inert gas can remove O₂ from the chamber 130. Hence, even if a spontaneously combustible metal-organic material is used, the layer formation process can be safely performed.

According to this embodiment, the chamber 130 is not filled with the material gas, but the atmosphere of the material gas is formed only in a local space on the surface of the workpiece W. Therefore, a layer formation space can be small, and an amount of material gas to be used can also be small.

Next, another embodiment of the present invention will be described with reference to FIGS. 5 and 6. FIG. 5 is a schematic view showing a layer forming apparatus according to another embodiment of the present invention, and FIG. 6 is a schematic view of the embodiment as viewed from a direction indicated by arrow VI in FIG. 5. Structures and operations which are identical to those of the embodiment shown in FIG. 4 will not be repetitively described below.

As shown FIGS. 5 and 6, a material supply section 119 is mounted on a reciprocation mechanism 127 extending parallel to the surface of the workpiece W, so that the material supply section 119 is moved by the reciprocation mechanism 127 in a direction parallel to the surface of the workpiece W at a desired speed. The material supply section 119 has a supply port 119a of a rectangular shape having a smaller width along a moving direction thereof than a width along a direction perpendicular to the moving direction. This longitudinal width is slightly larger than a width of the workpiece W, as shown in FIG. 6.

The material supply section 119 stays away from the workpiece W before and after the layer forming process. During the layer forming process, the material supply section 119 sweeps horizontally over the workpiece W on the upper surface of the workpiece holding section 100 from one end of the workpiece W to another. During this operation, a distance between the supply port 119a of the material supply section 119 and the surface of the workpiece W is kept constant. As described above, since the supply port 119a of the material supply section 119 is smaller than the surface of the workpiece W, the material gas is supplied only onto part of the surface of the workpiece W. However, because the material supply section 119 is moved parallel to the surface of the workpiece W, it is possible to supply the material gas to a desired area of the workpiece W. The supply port 119a of the material supply section 119 and the workpiece W may be moved relative to each other, and the workpiece W may be moved.

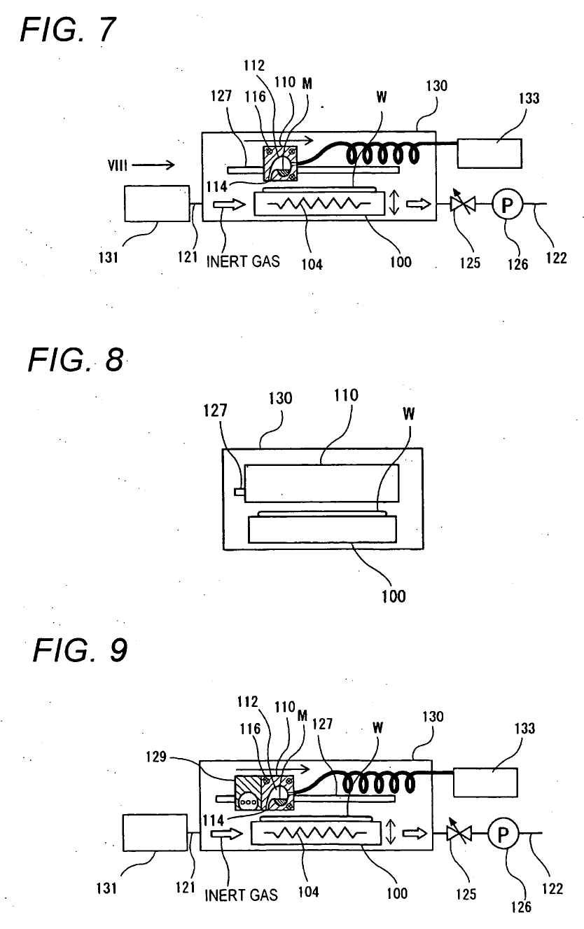

FIGS. 7 and 8 are schematic views showing a layer forming apparatus according to another embodiment of the present invention. FIG. 8 is the schematic view of the embodiment as viewed from a direction indicated by arrow VIII in FIG. 7. Structures and operations which are identical to those of the embodiment shown in FIG. 5 will not be repetitively described below.

The layer forming apparatus according to this embodiment uses a material vaporizing supply unit 110 having a material vaporizing section and a material supply section which are integrally combined. This material vaporizing supply unit 110 has a storage section 112 for storing the metal-organic material (solid or liquid) M, and a slit-shaped ejection port (supply port) 114 which has a gradually narrowed path extending from the storage section 112 and opens at a lower surface of the material vaporizing supply unit 110. A second heater 116 for heating and vaporizing the metal-organic material M is embedded in the material vaporizing supply unit 110.

An inert gas supply source 133 supplies an inert gas (a carrier gas), such as nitrogen, into the material vaporizing supply unit 110. The material vaporizing supply unit 110 is arranged such that the ejection port 114 faces the surface of the workpiece W. With this arrangement, the gaseous metal-organic material is carried by the inert gas and is ejected as the material gas to the workpiece W through the ejection port 114 to thereby locally form an atmosphere of the material gas on the surface of the workpiece W. In order to keep the temperature of the entire material vaporizing supply unit 110 constant, the material vaporizing supply unit 110 is preferably made from isothermal metal such as aluminum.

The material vaporizing supply unit 110 is mounted on reciprocation mechanism 127 extending parallel to the surface of the workpiece W, so that the material vaporizing supply unit 110 is moved by the reciprocation mechanism 127 in a direction parallel to the surface of the workpiece W at a desired speed. A longitudinal width of the ejection port 114 is slightly larger than the width of the workpiece W.

The material vaporizing supply unit 110 stays away from the workpiece W before and after the layer forming process. During the layer forming process, the material vaporizing supply unit 110 sweeps horizontally over the workpiece W on the upper surface of the workpiece holding section 100 from one end of the workpiece W to another. During this operation, a distance between the ejection port 114 of the material vaporizing supply unit 110 and the surface of the workpiece W is kept constant. As described above, since the ejection port 114 of the material vaporizing supply unit 110 is smaller than the surface of the workpiece W, the material gas is supplied only onto part of the surface of the workpiece W. However, because the material vaporizing supply unit 110 is moved parallel to the surface of the workpiece W, it is possible to supply the material gas to a desired area of the workpiece W. The ejection port 114 of the material vaporizing supply unit 110 and the workpiece W may be moved relative to each other, and the workpiece W may be moved.

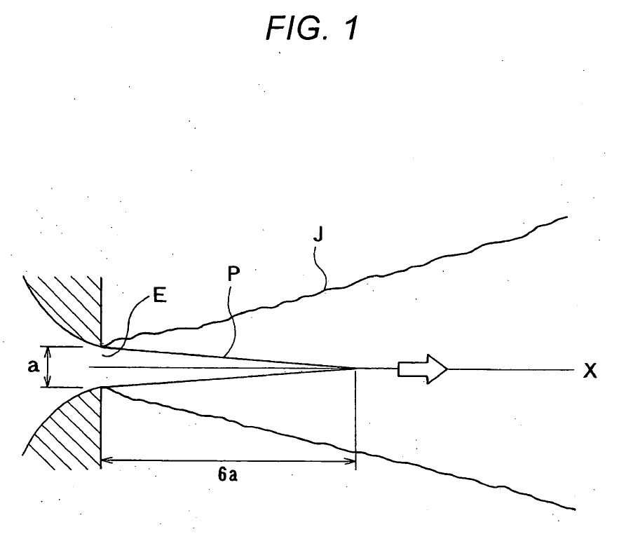

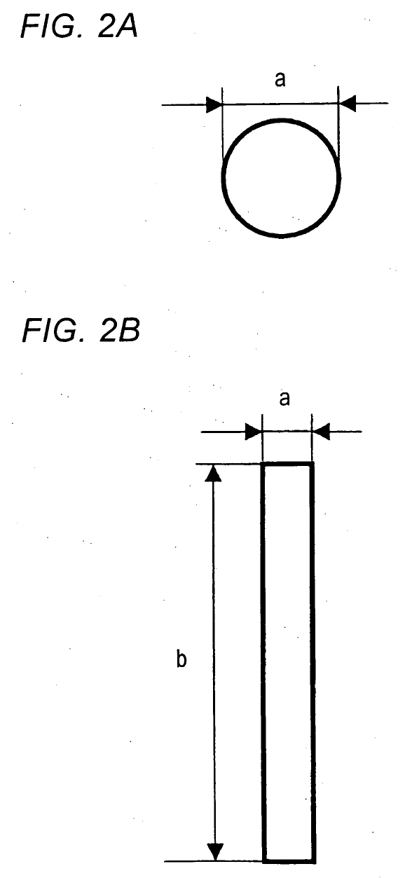

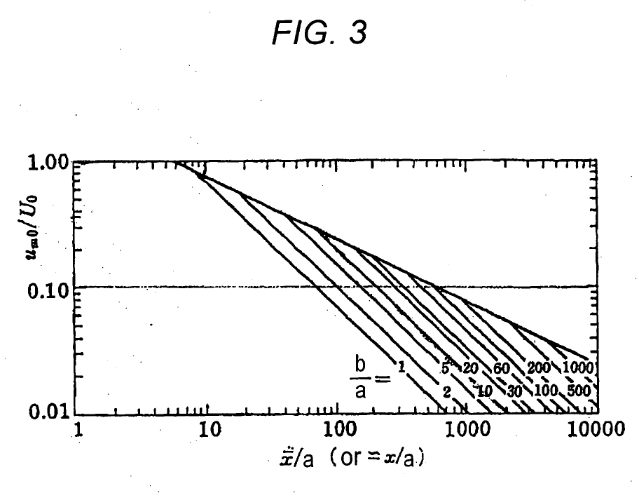

In this embodiment also, the workpiece holding section 100 is vertically movable so that the distance between the workpiece W and the ejection port 114 can be adjusted. Accordingly, the layer forming process can be performed with the distance from the ejection port 114 to the surface of the workpiece W being not more than six times the minimal width of the ejection port 114 (see FIG. 1).

FIG. 9 is a schematic view showing a layer forming apparatus according to another embodiment of the present invention. This layer forming apparatus has basically the same structure as that of the layer forming apparatus shown in FIGS. 7 and 8, but is different from the above layer forming apparatus in that a third heater 129 is provided adjacent to the material vaporizing supply unit 110.

In this embodiment, the material vaporizing supply unit 110 and the heater 129 are mounted on reciprocation mechanism 127 extending parallel to the surface of the workpiece W, so that the material vaporizing supply unit 110 and the heater 129 are moved by the reciprocation mechanism 127 in a direction parallel to the surface of the workpiece W at a desired speed. The heater 129 is provided at the rear of the material vaporizing supply unit 110 with respect to the moving direction thereof. A longitudinal width of the heater 129 is substantially equal to a longitudinal width of the material vaporizing supply unit 110.

During the layer forming process, the material vaporizing supply unit 110 is moved in the direction indicated by arrow in FIG. 9, and ejects the material gas containing the metal-organic material M to the surface of the workpiece W. The heater 129 heats and anneals the metal-organic material M on the surface of the workpiece W. In this manner, by annealing the layer using the heater 129 simultaneously with the layer formation and by repeating the layer formation and the annealing process at least two times, the resulting layer can have a desired thickness. Although the material vaporizing supply unit 110 and the heater 129 are moved in this embodiment, the manner of movement is not limited so long as the ejection port 114 of the material vaporizing supply unit 110 and the workpiece W are moved relative to each other. For example, the workpiece W may be moved.

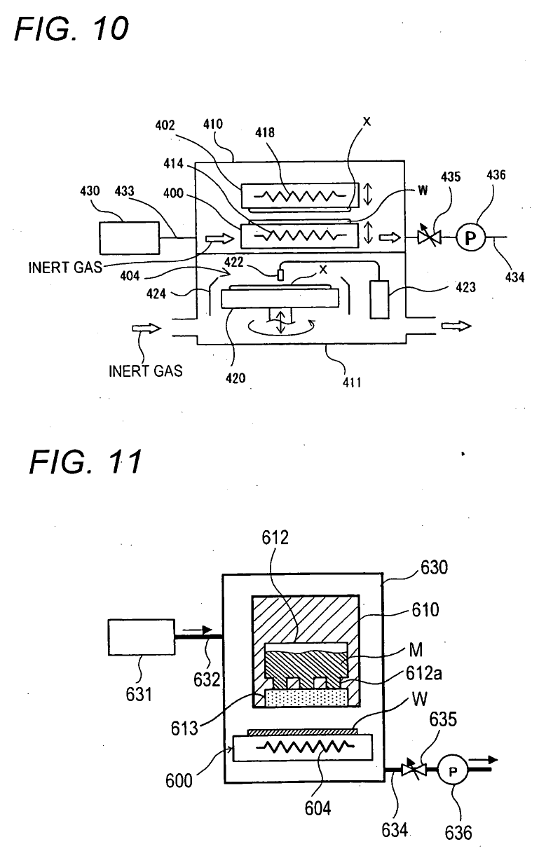

FIG. 10 is a schematic view showing a layer forming apparatus according to another embodiment of the present invention. As shown in FIG. 10, this layer forming apparatus comprises a workpiece holding section 400 for holding the workpiece W with its surface facing upwardly, a material-supply-member holding section 402 for holding a material supply member X having a coating film of the metal-organic material with its surface facing downwardly, a spin coater 404 for coating the material supply member X with the metal-organic material to form the coating film, and a robot (not shown in the drawings) for transferring the workpiece W and the material supply member X. The workpiece holding section 400 and the material-supply-member holding section 402 are housed in a chamber 410, and the spin coater 404 is housed in a chamber 411. The chamber 410 is placed on the chamber 411, so that the apparatus as a whole can be compact. Alternatively, the chamber 411 may be placed on the chamber 410.

The material-supply-member holding section 402 serves as a material vaporizing section for producing a material gas by vaporizing the metal-organic material which is in a solid or liquid state at a room temperature. The material supply member X coated with the metal-organic material serves as a material supply section for locally forming an atmosphere of the material gas on the surface of the workpiece W so as to expose the surface of the workpiece W to the atmosphere of the material gas to thereby form a metal layer or a metal compound layer on the surface of the workpiece W The workpiece holding section 400 has a vacuum chuck mechanism (not shown in the drawings) on an upper surface thereof, so that the workpiece W is held on the upper surface of the workpiece holding section 400 by the vacuum chuck mechanism. Inside the workpiece holding section 400, a first heater 414 is embedded for heating the workpiece W. The workpiece W is heated by the heater 414 to a temperature of, for example, 150° C. The workpiece holding section 400 of this embodiment is rotatable.

The material-supply-member holding section 402 has a vacuum chuck mechanism (not shown in the drawings) on a lower surface thereof, so that the material supply member X, coated with the metal-organic material, is held on the lower surface of the material-supply-member holding section 402 by the vacuum chuck mechanism. Inside the material-supply-member holding section 402, a second heater 418 is embedded for heating the material supply member X. The material supply member X is heated by the heater 418 to a temperature of, for example, 70° C., so that the metal-organic material in the form of coating film on the material supply member X is vaporized. Alternatively, the coating film of the metal-organic material on the material supply member X can be vaporized by convection heat or radiant heat from the surface of the workpiece W heated by the heater 414.

The spin coater 404 has a holder 420 for holding and rotating the material supply member X, a nozzle 422 for supplying the metal-organic material onto the upper surface of the material supply member X, a storage section 423 for storing the metal-organic material, and a cover 424 surrounding the holder 420.

The chamber 410 is connected to a gas-introduction pipe 433 for introducing an inert gas (e.g., nitrogen or argon) from an inert gas supply source 430 into the chamber 410. The chamber 410 is further connected to a gas-discharge pipe 434 for discharging the inert gas from the chamber 410. The gas-discharge pipe 434 is coupled to a vacuum pump 436 via a flow rate adjustment valve 435. Pressure in the chamber 410 can be kept at a desired pressure by adjusting a flow rate of the inert gas from the inert gas supply source 430 and the flow rate adjustment valve 435. For example, pressure in the chamber 410 is set to be the atmospheric pressure. Similarly, the chamber 411 is coupled to an inert gas supply source, a flow rate adjustment valve, a vacuum pump (all of these are not shown in the drawings), so that a flow of the inert gas, such as nitrogen or argon, is formed in the chamber 411.

In this layer forming apparatus, the workpiece W is first attracted to the upper surface of the workpiece holding section 400, and then the material supply member X is transferred by the robot to the spin coater 404. In the spin coater 404, while the material supply member X is rotated by the holder 420, the metal-organic material is supplied through the nozzle 422 to thereby coat the surface in its entirety of the material supply member X with the metal-organic material.

The material supply member X, coated with the metal-organic material, is transferred by the robot from the chamber 411 to the chamber 410. Then, the material-supply-member holding section 402 is lowered to hold the material supply member X on its lower surface. The material supply member X is held by the material-supply-member holding section 402 so as to face the workpiece W. A distance between the workpiece W and the material supply member X is not more than 3 mm, preferably in a range of 0.5 mm to 1 mm.

The material-supply-member holding section 402 is heated in advance by the heater 418. As the material supply member X is heated by the heater 418, the metal-organic material is vaporized from the coating film on the material supply member X, and an atmosphere of the gaseous metal-organic material (i.e., the material gas) is locally formed on the surface of the workpiece W. i.e., in a space between the workpiece W and the material supply member X. As a result, the surface of the workpiece W is exposed to the material gas, and a metal layer or a metal compound layer is thus formed on the surface of the workpiece W.

The material supply member X is heated by the heater 418 to a temperature at which the metal-organic material can be vaporized, and this temperature is preferably not more than the decomposition temperature of the metal-organic material. In order to substantially uniformly vaporize the metal-organic material, it is preferable to substantially uniformly heat the surface of the material supply member X. Further, a surface temperature of the material supply member X is preferably lower than a surface temperature of the workpiece W. In other words, the temperature of the metal-organic material heated by the heater 418 is preferably lower than the temperature of the workpiece W heated by the heater 414. Furthermore, during the layer forming process, it is preferable to heat the workpiece W by the heater 414 and to adjust the temperature of the workpiece W so that the layer is uniformly formed on the workpiece W. It is also preferable to rotate the workpiece holding section 400 during the layer forming process.

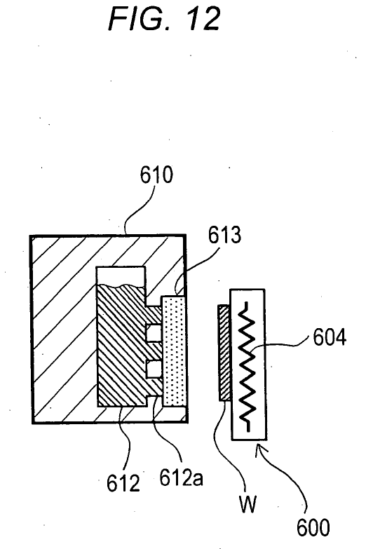

FIG. 11 is a schematic view showing a layer forming apparatus according to another embodiment of the present invention. This layer forming apparatus is operated so as to impregnate an impregnation member with the liquid metal-organic material to allow a surface of the impregnation member to retain the metal-organic material at all times, locally form an atmosphere of the material gas on the surface of the workpiece, and expose the surface of the workpiece to the atmosphere of the material gas to thereby form a layer.

As shown in FIG. 11, the layer forming apparatus comprises a workpiece holding section (susceptor) 600 for holding the workpiece W with its surface facing upwardly, and a material vaporizing supply unit 610 for vaporizing the metal-organic material M and supplying the vaporized metal-organic material M to the surface of the workpiece W held by the workpiece holding section 600. The workpiece holding section 600 and the material vaporizing supply unit 610 are housed in a chamber 630 and are thus isolated from outside by the chamber 630.

The material vaporizing supply unit 610 serves as a material vaporizing section for producing the material gas by vaporizing the metal-organic material which is in a liquid state at a room temperature, and further serves as a material supply section for locally forming an atmosphere of the material gas on the surface of the workpiece W so as to expose the surface of the workpiece W to the atmosphere of the material gas to thereby form a metal layer or a metal compound layer on the surface of the workpiece W.

The workpiece holding section 600 has an electrostatic chuck mechanism (not shown in the drawings) on an upper surface thereof, so that the workpiece W is held on the upper surface of the workpiece holding section 600 by an electrostatic force of the electrostatic chuck mechanism. Inside the workpiece holding section 600, a first heater (a workpiece heating section) 604 is embedded for heating the workpiece W held on the upper surface of the workpiece holding section 600. By supplying an electric current to the heater 604, the workpiece W is heated to a temperature (e.g., 150° C.) higher than the decomposition temperature of the metal-organic material M. The temperature of the workpiece W is changed according to the metal-organic material used.

The chamber 630 is connected to a gas-introduction pipe 632 for introducing an inert gas (e.g., nitrogen or argon) from an inert gas supply source 631 into the chamber 630. The chamber 630 is further connected to a gas-discharge pipe 634 for discharging the inert gas from the chamber 630. The gas-discharge pipe 634 is coupled to a vacuum pump 636 via a flow rate adjustment valve 635. Pressure in the chamber 630 can be kept at a desired pressure by adjusting a flow rate of the inert gas from the inert gas supply source 631 and the flow rate adjustment valve 635. For example, the pressure in the chamber 630 is set to be the atmospheric pressure.

A storage section 612 for storing the metal-organic material M is formed in the material vaporizing supply unit 610. This storage section 612 serves as an isothermal chamber that can retain the metal-organic material M in a liquid state. The storage section 612 is filled with the liquid metal-organic material M. An impregnation member 613, which is to be impregnated with the liquid metal-organic material M in the storage section 612, is provided below the storage section 612, and is in fluid communication with the storage section 612 through holes 612a. The impregnation member 613 has an exposed lower surface facing the workpiece W placed on the workpiece holding section 600. A porous material, a nonwoven fabric, or a woven fabric is preferably used as the impregnation member 613.

With this structure, the impregnation member 613 is impregnated, due to capillarity, with the liquid metal-organic material M retained in the storage section 612 at all times. At the lower surface of the impregnation member 613, the metal-organic material M is vaporized by heat transferred from the surface of the workpiece W being heated, thus locally forming an atmosphere of the vaporized metal-organic material M (i.e., the material gas atmosphere) on the surface of the workpiece W. As a result, the surface of the workpiece W is exposed to the material gas atmosphere, whereby a metal layer or a metal compound layer is formed on the surface of the workpiece W. Use of such impregnation member 613 allows stable supply of the metal-organic material M to the surface of the workpiece W. It is preferable that a distance from the surface of the impregnation member 613 to the surface of the workpiece W is set to be not more than 10 mm, more preferably not more than 3 mm. These values are determined from the viewpoint of forming the local atmosphere of the material gas on the surface of the workpiece W. A heater for heating the metal-organic material M retained by the impregnation member 613 may be provided adjacent to the impregnation member 613.

FIG. 12 is a schematic view showing another structure of the embodiment. As shown in FIG. 12, this layer forming apparatus has basically the same structure as that of the layer forming apparatus shown in FIG. 11, but is different in that the workpiece W, the workpiece holding section 600, and the impregnation member 613 are disposed vertically. In this example, because the impregnation member 613 is used in the material vaporizing supply unit 610, the metal-organic material M does not leak even if an installation angle of the impregnation member 613 is changed. Accordingly, an installation angle of the workpiece W and the workpiece holding section 600 can be set as desired, and design flexibility can be improved.

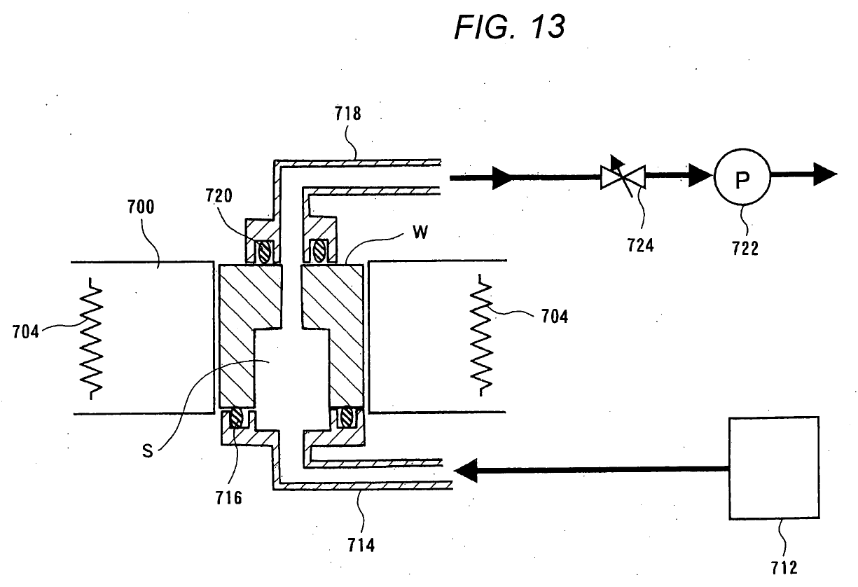

FIG. 13 is a schematic view showing a layer forming apparatus according to another embodiment of the present invention. This layer forming apparatus is designed to supply the material gas (i.e., the gaseous metal-organic material, or the mixture of the inert gas and the gaseous metal-organic material, or the aerosol of the powdery metal-organic material) into a space formed in a workpiece to thereby form a metal layer or a metal compound layer on a surface defining the space.

As shown in FIG. 13, the layer forming apparatus comprises a workpiece holding section (susceptor) 700 for holding a workpiece W, a material vaporizing section 712 for heating and vaporizing the metal-organic material to produce the material gas, a material supply pipe (material supply passage) 714 for supplying the material gas into a space S formed in the workpiece W, and a material discharge pipe (material discharge passage) 718 for discharging the material gas and other substances from the space S. In this embodiment, a chamber and an inert gas supply source are not provided.

Inside the workpiece holding section 700, first heaters (each as a workpiece heating section) 704 are embedded for heating the workpiece W. By supplying an electric current to the heaters 704, the workpiece W is heated to a temperature (e.g., 150° C.) higher than the decomposition temperature of the metal-organic material. The temperature of the workpiece W is changed according to the metal-organic material used.

The material supply pipe 714 is connected to the space S in the workpiece W, and a seal member 716 (e.g., an O-ring) is provided between the workpiece W and the material supply pipe 714 so as to seal a gap therebetween. The material discharge pipe 718 is connected to the space S at the opposite side of the material supply pipe 714, and a seal member 720 (e.g., an O-ring) is provided between the workpiece W and the material discharge pipe 718 so as to seal a gap therebetween. The material discharge pipe 718 communicates with a vacuum pump 722, so that the material gas and the decomposition products are discharged by the vacuum pump 722 from the space S through the material discharge pipe 718. A flow rate adjustment valve 724 is provided upstream of the vacuum pump 722.

With this structure, the vacuum pump 722 is operated to evacuate the space S in the workpiece W through the material discharge pipe 718, and the material gas is introduced into the space S from the material vaporizing section 712 through the material supply pipe 714. As a result, an atmosphere of the material gas is formed in the space S, whereby a metal layer or a metal compound layer is formed on a surface defining the space S. During the layer formation, it is preferable to heat the workpiece W by the heaters 704 and to adjust the temperature of the workpiece W so that the layer is uniformly formed.

The layer forming apparatus according to this embodiment is suitable for use in forming a layer on a workpiece having a surface with a complex shape. For example, even in a case of forming a layer on a curved surface, e.g., an inner circumferential surface of a cylindrical workpiece, it is easy to optimize layer forming conditions, and hence the layer can be uniformly formed. More specifically, because the atmosphere of the material gas can be locally formed only on a portion where the layer is to be formed (e.g., in this embodiment, only on the surface defining the space S), there is no need to consider an outside atmosphere in optimizing the layer forming conditions. Accordingly, the layer formation in a region where reaction is rate-limiting can be easily performed.

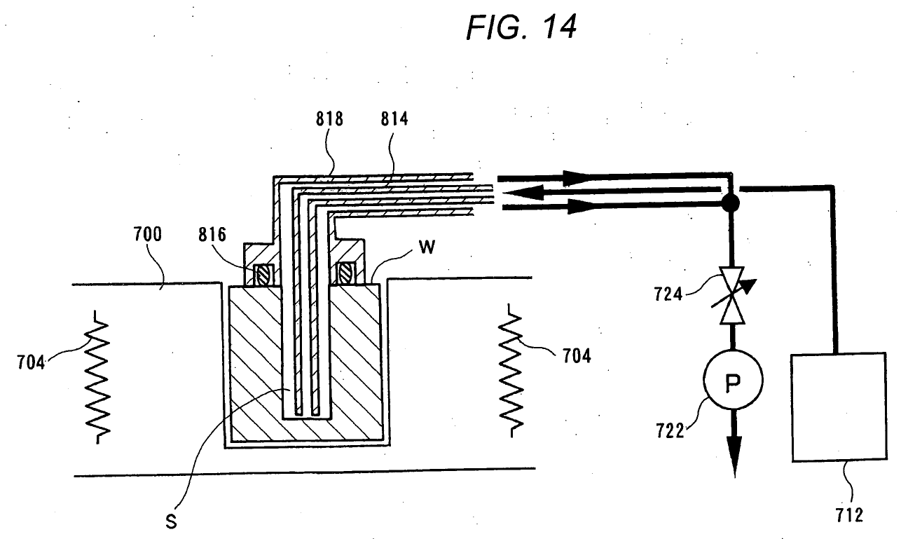

FIG. 14 is a schematic view showing a layer forming apparatus according to another embodiment of the present invention. Structures and operations which are identical to those of the embodiment shown in FIG. 13 will not be repetitively described below.

As shown in FIG. 14, this layer forming apparatus is designed to form a layer on an inner surface of a recessed portion defining a space S in a workpiece W. More specifically, the layer forming apparatus comprises a material supply pipe 814 serving as a material supply passage connected to material vaporizing section 712, and a material discharge pipe 818 serving as a material discharge passage connected to vacuum pump 722. The material supply pipe 814 and the material discharge pipe 818 are provided as a double pipe. A seal member 816 (e.g., an O-ring) is provided between the material discharge pipe (outer pipe) 818 and the workpiece W. The material supply pipe (inner pipe) 814 is inserted into the recessed space S in the workpiece W. The layer forming apparatus having such a structure can form a layer on the workpiece having a surface of a diverse and complex shape.

Although this embodiment has the double pipe structure in which the material supply pipe 814 is provided as the inner pipe and the material discharge pipe 818 is provided as the outer pipe, the material supply pipe 814 may be provided as the outer pipe and the material discharge pipe 818 may be provided as the inner pipe.

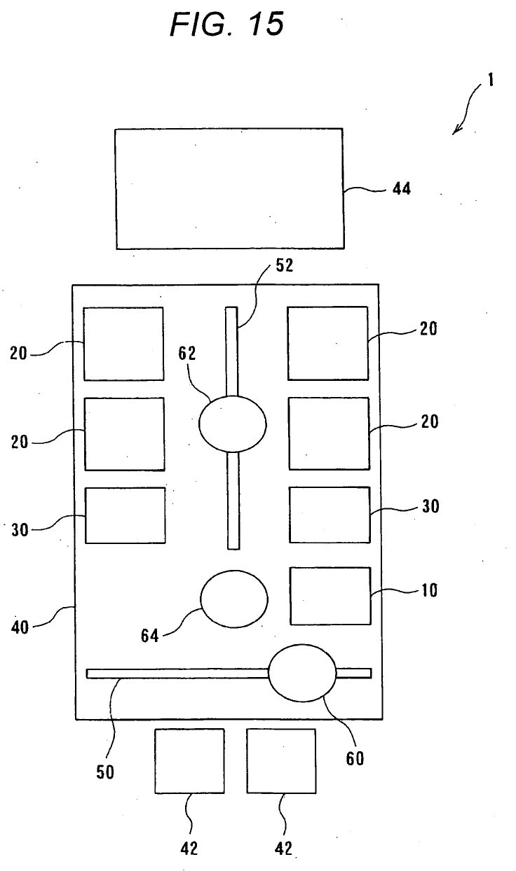

The workpiece to be used in the above embodiments is, for example, a semiconductor wafer, a ceramic, a resin, or a metal. The layer forming apparatus according to the present invention can be used in fabrication of a semiconductor, a micro electro mechanical systems (MEMS), a flat panel display (FPD), and the like. Next, an example of application of the above layer forming apparatus will be described with reference to FIGS. 15 through 19B. In this example, the layer forming apparatus is used for forming a metal layer or a metal compound layer on a surface of a semiconductor substrate (a semiconductor wafer) as a workpiece. In FIGS. 15 through 19B, identical or corresponding components are denoted by the same reference numerals, and will not be repetitively described.

FIG. 15 is a plan view showing a workpiece processing apparatus 1 having a layer forming apparatus according to the present invention. As shown in FIG. 15, the workpiece processing apparatus 1 comprises a layer forming unit 10 for forming a metal layer or a metal compound layer on a surface of a workpiece, such as a semiconductor wafer (substrate), having a fine trench structure, four electroplating units 20 for electroplating the workpiece after the layer formation, and two etching and cleaning units 30 for etching, cleaning and drying the workpiece after electroplating. All of these units are housed in a rectangular flame 40. Workpiece transfer vessels 42, each can house a number of workpieces therein, are detachably provided on an end portion of a longitudinal side of the flame 40. Examples of the workpiece transfer vessels 42 include SMIF (Standard Manufacturing Interface) pod or FOUP (Front Opening Unified Pod). A chemical liquid management section 44 for managing a chemical liquid, e.g., plating solution, is provided outside the flame 40,

Inside the flame 40, a rail 50 is installed along an arrangement direction of the workpiece transfer vessels 42, and a first transfer robot 60 is provided on the rail 50. A rail 52 is installed along an arrangement direction of the electroplating units 20 and the etching and cleaning unit 30, and a second transfer robot 62 is provided on the rail 52. Further, a third transfer robot 64 is provided between the first transfer robot 60 and the second transfer robot 62 at a position near the layer forming unit.

The first transfer robot 60 is operable to transfer the workpiece between the workpiece transfer vessels 42, the third transfer robot 64, and the layer forming unit 10. The third transfer robot 64 is operable to transfer the workpiece between the layer forming unit 10 and the second transfer robot 62. The second transfer robot 62 is operable to transfer the workpiece between the third transfer robot 64, the electroplating units 20, and the etching and cleaning units 30.

The workpiece is introduced into the workpiece processing apparatus 1 via the workpiece transfer vessels 4, and is transferred by the first transfer robot 60 to the layer forming unit 10. In this layer forming unit 10, as described above, a layer is formed on the workpiece by vaporizing the metal-organic material. Thereafter, the workpiece is transferred by the third transfer robot 64 and the second transfer robot 62 to the electroplating unit 20, where plating is performed on the workpiece. After plating, the workpiece is transferred by the second transfer robot 62 to the etching and cleaning unit 30, where a film, formed by plating, is etched away from an edge portion (bevel portion) of the workpiece and the workpiece is cleaned and dried.

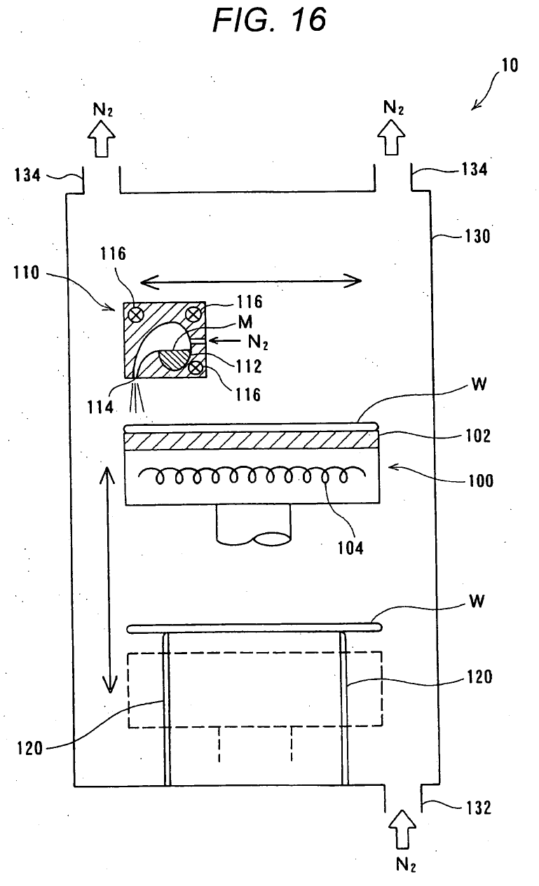

The layer forming apparatus according to any one of the above embodiments can be used as the layer forming unit 10. In this example, the layer forming unit 10 has substantially the same structure as that of the layer forming apparatus shown in FIG. 7. Next, this layer forming unit 10 will be described with reference to FIG. 16.

FIG. 16 is a schematic view showing the layer forming unit 10 shown in FIG. 15. This layer forming unit 10 is operable to form on a surface of the workpiece a layer of a substance contained in the metal-organic material having vapor pressure not more than atmospheric pressure. As shown in FIG. 16, the layer forming unit 10 comprises workpiece holding section (susceptor) 100 for holding the workpiece W with its surface facing upwardly, material vaporizing supply unit 110 for vaporizing the metal-organic material and ejecting the vaporized metal-organic material to the surface of the workpiece W held by the workpiece holding section 100, and a plurality of pins 120 for supporting the workpiece W introduced by the first transfer robot 60 to the layer forming unit 10. The workpiece holding section 100, the material vaporizing supply unit 110, and the pins 120 are housed in chamber 130 and are thus isolated from outside by the chamber 130.

The workpiece holding section 100 has a vacuum chuck mechanism 102 on an upper surface thereof, so that the workpiece W is held on the upper surface of the workpiece holding section 100 by the vacuum chuck mechanism 102. Inside the workpiece holding section 100, heater 104 is embedded for heating the workpiece W attracted by the vacuum chuck mechanism 102 to the upper surface of the workpiece holding section 100. The workpiece W is heated by the heater 104 to a temperature (e.g., 150° C.) higher than the decomposition temperature of the metal-organic material M. The temperature of the workpiece W to be raised is changed according to the metal-organic material used. This temperature is preferably in a range of 120° C. to 300° C. The workpiece holding section 100 is vertically movable between a position below the workpiece W supported by the pins 120 and a position near the material vaporizing supply unit 110.

As shown in FIG. 16, the material vaporizing supply unit 110 has storage section 112 for storing the metal-organic material (solid or liquid) M, and ejection port 114 which has a gradually narrowed path extending from the storage section 112 and opens at a lower surface of the material vaporizing supply unit 110. Heaters 116 for heating and vaporizing the metal-organic material M are embedded in the material vaporizing supply unit 110. An inert gas, such as nitrogen, is introduced into the material vaporizing supply unit 110.

The metal-organic material M is heated by the heaters 116 to a temperature (e.g., 70° C.) at which the metal-organic material M can be vaporized, whereby the metal-organic material M is vaporized. This temperature is preferably set to be a temperature at which the vaporized metal-organic material M can be supplied to the surface of the workpiece in a controllable manner, and is preferably not more than a boiling temperature of the metal-organic material. The material vaporizing supply unit 110 in this embodiment is operable to horizontally move over the workpiece W held on the upper surface of the workpiece holding section 100 from one end of the workpiece W to another.

A gas-introduction port 132 for introducing the inert gas (e.g., nitrogen or argon) into the chamber 130 is provided on a lower portion of the chamber 130, and gas-discharge ports 134 for discharging the inert gas from the chamber 130 is provided on an upper portion of the chamber 130.

The workpiece W is introduced into the chamber 130, and is placed onto upper portions of the pins 120. Then, the workpiece holding section 100, located below the workpiece W, is elevated to receive the workpiece W from the pins 120, and the workpiece W is attracted to the upper surface of the workpiece holding section 100 by the vacuum chuck mechanism 102.

The workpiece holding section 100, holding the workpiece W, keeps moving upwardly until it reaches a position near the material vaporizing supply unit 110. After elevation of the workpiece holding section 100, the heaters 116 of the material vaporizing supply unit 110 heat the metal-organic material M in the storage section 112 to vaporize the metal-organic material M. The vaporized metal-organic material M is ejected through the ejection port 114 to the upper surface of the workpiece W, whereby a metal layer or a metal compound layer is formed on the upper surface of the workpiece W During this layer formation, it is preferable to heat the workpiece W by the heater 104 of the workpiece holding section 100 and to adjust the temperature of the workpiece W so that the layer is uniformly formed. During the layer formation, the material vaporizing supply unit 110 is horizontally moved so as to form the layer on the entire surface of the workpiece W. In order to uniformly supply the vapor of the metal-organic material onto the workpiece W, a rectifier may be provided so as to create a gas flow directed from the material vaporizing supply unit 110 to the workpiece W.

The workpiece W is then removed from the layer forming unit 10. A vacuum pump capable of producing an ultimate vacuum of, for example, about 0.01 Pa is used to evacuate the chamber 130 through the gas-discharge ports 134 to thereby discharge the vapor of the metal-organic material M used in the layer formation. Thereafter, the inert gas, such as dry nitrogen, is introduced into the chamber 130 through the gas-introduction port 132, and then the workpiece W having the layer thereon is removed from the layer forming unit 10. Alternatively, the layer forming unit 10 may have a load lock so that the workpiece W is removed via this load lock.

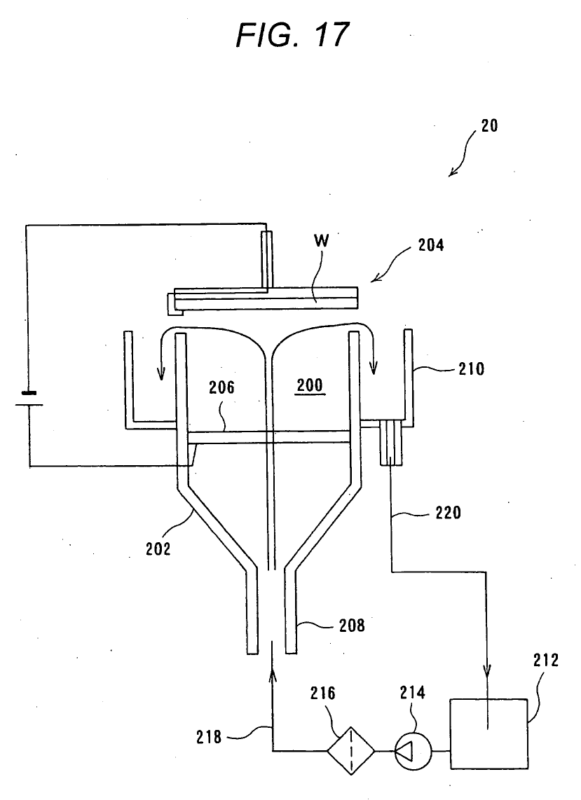

FIG. 17 is a schematic view showing the electroplating unit 20 shown in FIG. 15. As shown in FIG. 17, the electroplating unit comprises a cylindrical plating bath 202 having an upper opening for holding therein a plating solution 200, a head section 204 for detachably holding the workpiece W with its surface facing downwardly and operable to move the workpiece W to a position where the workpiece W covers the upper opening of the plating bath 202. A plate-shaped anode 206 is horizontally disposed in the plating bath 202, and is immersed in the plating solution 200. A peripheral portion of the workpiece W is in electrical communication with a cathode via electrode contacts provided on the head section 204. The anode 206 is made from a porous material or a mesh material.

A plating solution ejection pipe 208 for producing an upward jet of the plating solution is connected to a central portion of a bottom of the plating bath 202. A plating solution receiver 210 is provided around an upper portion of the plating bath 202. The plating solution ejection pipe 208 is connected to a plating solution supply pipe 218, which extends from a plating solution adjustment tank 212 and has a pump 214 and a filter 216. The above plating solution adjustment tank 212 is connected to a plating solution return pipe 220 extending from the plating solution receiver 210.

This electroplating unit 20 is operated as follows. The workpiece W is held by the head section 204 with the surface of the workpiece W facing downwardly, and is immersed in the plating solution 200 from the upper portion of the plating bath 202. Then, a predetermined voltage is applied between the anode 206 and the workpiece (cathode) W while the pump 214 supplies the plating solution from the plating solution adjustment tank 212 to the bottom of the plating bath 202 to thereby produce the upward jet of the plating solution directed perpendicular to the lower surface of the workpiece W. In this manner, plating current flows between the anode 206 and the workpiece W to form a film on the lower surface of the workpiece W. During plating, the plating solution 200 overflows the plating bath 202 into the plating solution receiver 210, and is returned to the plating solution adjustment tank 212.

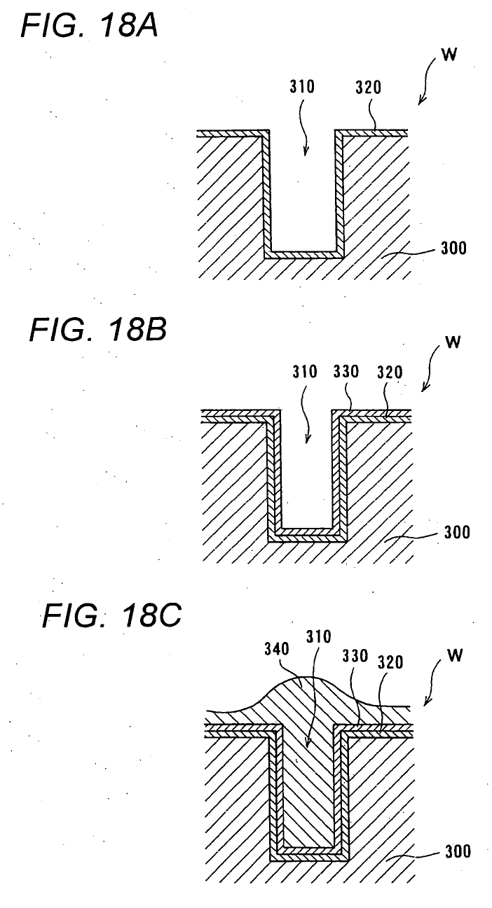

This workpiece processing apparatus is suitable for use in performing the following processes. First, an interconnect trench 310 is formed on a surface of an interlayer dielectric 300 composed of SiO₂ or a low-k material, as shown in FIG. 18A. A barrier metal layer 320 of Ta is formed on the surface of the interlayer dielectric 300 using sputtering or the like. The workpiece W having the barrier metal layer 320 thereon is introduced into the layer forming unit 10 of the above-mentioned workpiece processing apparatus 1. In this layer forming unit 10, an organic Co is vaporized, and Co is deposited on a surface of the barrier metal layer 320. As a result, as shown in FIG. 18B, a Co layer 330 is uniformly formed on the surface of the barrier metal layer 320.

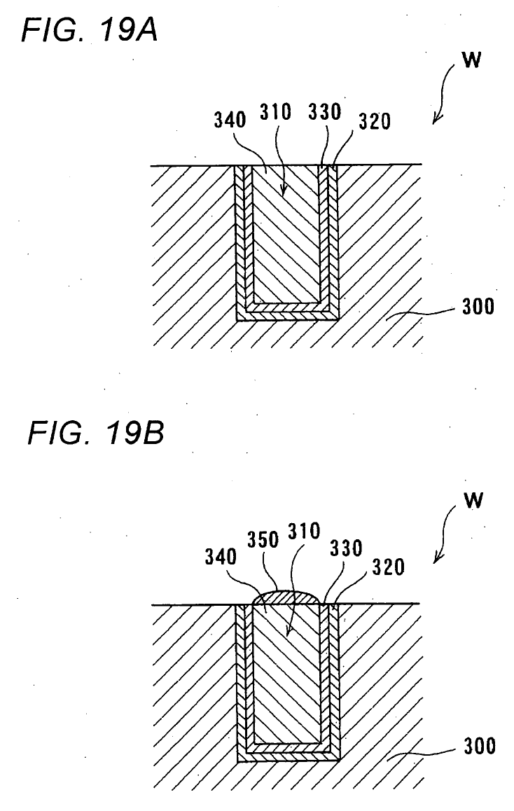

Then, the workpiece W is introduced to the above-mentioned electroplating unit 20. In this electroplating unit 20, electroplating is performed using the Co layer 330 as a seed layer to thereby form a copper film 340 on a surface of the Co layer 330, as shown in FIG. 18C. As a result, the interconnect trench 310 is filled with the copper film 340. The workpiece W, having the interconnect trench 310 filled with the copper film 340, is transferred from the workpiece processing apparatus 1 to a CMP apparatus. In this CMP apparatus, as shown in FIG. 19A, the excess copper film 340 is removed by chemical mechanical polishing until an exposed surface of the interlayer dielectric 300 appears. Thereafter, the workpiece W is transferred from the CMP apparatus to an electroless plating apparatus. In this electroless plating apparatus, the workpiece W is plated with CoWP by electroless plating, so that a CoWP layer 350 is selectively formed on the surface of the copper film 340 filling the interconnect trench 310, as shown in FIG. 19B.

According to the interconnect structure produced in this manner, the Co layer 330 is formed between the copper film 340, filling the interconnect trench 310, and the barrier metal layer 320, and the CoWP layer 350 is formed on the surface of the copper film 340 filling the interconnect trench 310. Therefore, the copper film 340 is covered with the Co layer 330 and the CoWP layer (i.e., metal layer composed mainly of Co) 350 which are the same type of metal. Hence, reliability of an interface between the Co layer 330 and the CoWP layer 350 can be enhanced, and adhesion to cooper can also be improved. As a result, reliability against the copper diffusion can be enhanced.

It is preferable that the decomposition temperature of the metal-organic material to be used in the layer forming unit 10 is significantly higher than a temperature at which the metal-organic material can be vaporized. Use of such material allows vaporization of the metal-organic material under the atmospheric pressure, and thus allows the layer forming unit to be combined with a wet processing unit, e.g., the electroplating unit. Therefore, the layer forming unit and the wet processing unit can be installed in a single workpiece processing apparatus, and hence the apparatus having a simple and space-saving structure can be realized. Further, because the layer forming unit and the wet processing unit can be installed in a single apparatus, a time between the layer forming process and the wet process can be shortened, and the time management can be easily performed.

Although the CMP apparatus and the electroless plating apparatus are provided separately from the workpiece processing apparatus 1 in this example, the CMP apparatus and the electroless plating apparatus may be incorporated into the workpiece processing apparatus 1. In the layer forming unit 10 of the workpiece processing apparatus 1, Co/Si may be deposited onto the surface of the workpiece W, and the deposited Co/Si may be heat-treated so as to form a silicide layer serving as the seed layer. Co may be thinly deposited onto a surface of a barrier metal layer of Ru using the layer forming unit 10 so that the growth of the copper film during electroplating in the electroplating unit 20 can be accelerated. It is preferable that at least one layer composed of a material selected from the group consisting of semiconductor, ceramic, resin, Ru, RuO₂, Cu, Ta, TaN, Ti, TiN, Si, SiO₂, low-k material, Co, P, CoP, CoWP, W, WSiC, WC, Ni, and Al is formed on the surface of the workpiece to be introduced into the layer forming unit 10.

The above embodiment shows an example in which the layer forming unit and the electroplating unit are used together. However, the wet processing unit to be used with the layer forming unit is not limited to the electroplating unit. For example, an electroless plating unit, a chemical mechanical polishing unit, an electrolytic etching unit, an electrolytic polishing unit, a chemical etching unit, a cleaning unit, or the like can be used as the wet processing unit. Further, the layer forming unit can be used together with a dry processing unit, such as an annealing unit, a CVD unit, or a gas etching unit. In this case, a metal layer or a metal compound layer is first formed on the workpiece by the layer forming unit, and then the workpiece is dry-processed.

Plural layer forming units may be provided so that different kinds of substances are used to form different metal layers or metal compound layers in the respective layer forming units. Alternatively, the gas or the metal-organic material may be replaced with a different kind so that the layer formation process is repeated several times in a single layer forming unit. In this case also, metal layers or metal compound layers, each composed of a different kind of substance, can be formed. Examples of the cleaning process to be performed after the layer forming process include contact cleaning (e.g., roll cleaning or pencil cleaning) and non-contact cleaning (e.g., ultrasonic liquid cleaning or IPA cleaning). After cleaning, the workpiece may be dried.

A database on a relationship between target temperature of the metal-organic material to be heated and corresponding target temperature of the workpiece to be heated may be stored in advance in a memory device for each kind of metal-organic material to be used for the layer formation. In this case, for example, sensors may be provided respectively for measuring a temperature of the workpiece and for measuring a temperature of the heater, so that the target temperature can be determined based on temperature signals from the sensors with reference to the database and the heater can be controlled in accordance with the target temperature obtained. With this structure, the temperature of the workpiece and the temperature of the metal-organic material can be within an appropriate temperature range.

A process recipe including the layer formation process is stored in a computer-readable storage medium, and is read as required. This process recipe is in the form of a database categorized according to the kind of workpiece to be processed and the kind of material to be formed, and this database is stored in the above-mentioned storage medium.

According to the present invention, a small space for the layer formation, saving of the metal-organic material, good adhesion between the workpiece and the layer, a uniform layer-thickness, and successive performing of the layer forming process and the wet or dry process in a single apparatus can be realized.

Although certain preferred embodiments of the present invention have been described, it should be understood that the present invention is not limited to the embodiments described above, and various changes and modifications may be made without departing from the scope of the present invention.

What is claimed is:

1. A layer forming method comprising:
heating a surface of a workpiece;
producing a material gas containing a metal-organic material by heating and vaporizing the metal-organic material in a solid or liquid state under pressure ranging from 0.01 Pa to atmospheric pressure;
locally forming an atmosphere of the material gas on the surface of the workpiece; and
forming a metal layer or a metal compound layer on the surface of the workpiece by exposing at least a portion of the surface of the workpiece to the atmosphere of the material gas.

2. The layer forming method according to claim 1, further comprising:
supplying the material gas through a supply port onto a portion of the surface of the workpiece facing the supply port; and
moving the supply port and the workpiece relative to one another with a distance between the supply port and the workpiece being kept constant to thereby locally form the atmosphere of the material gas on the surface of the workpiece,
wherein said supply port has an area equal to or smaller than that of the surface of the workpiece.

3. The layer forming method according to claim 2, further comprising:
providing a unit having a material vaporizing section for vaporizing the metal-organic material and the supply port which are integrally combined,
wherein said moving the supply port and the workpiece comprises moving the unit and the workpiece relative to one another.

4. The layer forming method according to claim 2, wherein the distance from the supply port to the surface of the workpiece is not more than six times a minimal width of the supply port.

5. The layer forming method according to claim 2, further comprising:
providing a heater adjacent to the supply port at a rear of the supply port with respect to a moving direction of the supply port;
annealing the layer by the heater simultaneously with said forming the layer; and
repeating said forming the layer and said annealing at least two times.

6. The layer forming method according to claim 1, further comprising:
providing an impregnation member so as to face the workpiece; and
impregnating the impregnation member with the metal-organic material in a liquid state,
wherein the metal-organic material retained by the impregnation member is heated and vaporized to thereby produce the material gas containing the metal-organic material.

7. The layer forming method according to claim 6, wherein the impregnation member comprises at least one of a porous material, a nonwoven fabric, and a woven fabric.

8. The layer forming method according to claim 6, wherein a distance from a surface of the impregnation member to the surface of the workpiece is set to be not more than 10 mm.

9. The layer forming method according to claim 1, further comprising:
preparing a workpiece having a space therein;
supplying the material gas into the space to thereby perform said locally forming the atmosphere of the material gas on the surface of the workpiece; and
discharging the material gas and decomposition products thereof from the space.

10. The layer forming method according to claim 9, wherein said supplying and said discharging are performed using two passages which are concentrically arranged.

11. The layer forming method according to claim 1, wherein said producing the material gas comprises:
coating a material supply member with the metal-organic material to form a coating film of the metal-organic material;
locating the material supply member so as to face the workpiece; and
heating the coating film of the metal-organic material on the material supply member to thereby vaporize the metal-organic material,
wherein a distance between the workpiece and the material supply member being not more than 3 mm.

12. The layer forming method according to claim 11, wherein said heating the coating film of the metal-organic material on the material supply member is performed by convection heat or radiant heat from the surface of the workpiece heated.

13. The layer forming method according to claim 1, wherein the metal-organic material contains at least one of cobalt, tungsten, platinum, aluminum, copper, molybdenum, manganese, and silicon.

14. The layer forming method according to claim 1, wherein the workpiece is a semiconductor wafer, a ceramic, a resin, or a metal.

15. The layer forming method according to claim 1, wherein the workpiece has thereon at least one layer composed of a material selected from the group consisting of semiconductor, ceramic, resin, Ru, RuO₂, Cu, Ta, TaN, Ti, TiN, Si, SiO₂, low-k material, Co, P, CoP, CoWP, W, WSiC, WC, Ni, and Al.

16. An interconnect forming method comprising:
forming a barrier metal layer on a surface of a workpiece having an interconnect trench;
forming a metal layer or a metal compound layer on the barrier metal layer using a method according to any one of claims 1 to 12;
performing electroplating using the metal layer or the metal compound layer as a seed layer to thereby fill the interconnect trench with a copper; and
removing part of the copper by chemical mechanical polishing.

17. The interconnect forming method according to claim 16, wherein the metal layer or the metal compound layer is a metal layer composed mainly of cobalt.

18. The interconnect forming method according to claim 17, further comprising:
performing electroless plating to selectively form a metal layer composed mainly of cobalt on a surface of the copper filling the interconnect trench.

19. A substrate interconnect structure comprising:
a copper filling an interconnect trench;
a barrier metal layer;
a metal layer composed mainly of cobalt and formed between said copper and said barrier metal layer; and
a metal layer composed mainly of cobalt and formed on an exposed surface of said copper,
wherein said metal layer formed between said copper and said barrier metal layer is a cobalt layer formed by a method according to any one of claims 1 to 12, and
wherein said metal layer on the exposed surface of said copper is formed by electroless plating.

20. A layer forming apparatus comprising:
a material vaporizing section for producing a material gas containing a metal-organic material by heating and vaporizing the metal-organic material in a solid or liquid state under pressure ranging from 0.01 Pa to atmospheric pressure;
a workpiece holding section for holding a workpiece;
a workpiece heating section for heating a surface of the workpiece to a temperature higher than a decomposition temperature of the metal-organic material vaporized by said material vaporizing section; and
a material supply section for locally forming an atmosphere of the material gas on the surface of the workpiece,
wherein said material supply section is operable to form a metal layer or a metal compound layer on the surface of the workpiece by exposing at least a portion of the surface of the workpiece to the atmosphere of the material gas.

21. The layer forming apparatus according to claim 20, further comprising:
a supply port for supplying the material gas onto a portion of the surface of the workpiece; and
a moving mechanism for moving said supply port and the workpiece, which faces said supply port, relative to one another with a distance between said supply port and the workpiece being kept constant,
wherein said supply port has an area equal to or smaller than that of the surface of the workpiece.

22. The layer forming apparatus according to claim 21, wherein:
said material vaporizing section and said material supply section are integrated into a unit; and
said moving mechanism is operable to provide relative movement between said unit and the workpiece.

23. The layer forming apparatus according to claim 21, wherein the distance from said supply port to the surface of the workpiece is not more than six times a minimal width of said supply port.

24. The layer forming apparatus according to claim 21, further comprising:
a heater provided adjacent to said supply port at a rear of said supply port with respect to a moving direction of said supply port.

25. The layer forming apparatus according to claim 21, wherein:
said material supply section includes an impregnation member disposed so as to face the workpiece; and
said impregnation member is impregnated with the metal-organic material in a liquid state.

26. The layer forming apparatus according to claim 25, wherein said impregnation member comprises at least one of a porous material, a nonwoven fabric, and a woven fabric.

27. The layer forming apparatus according to claim 25, wherein a distance from a surface of said impregnation member to the surface of the workpiece is not more than 10 mm.

28. The layer forming apparatus according to claim 20, wherein:
said material supply section has a material supply passage for supplying the material gas into a space formed in the workpiece, said material supply passage being coupled to the space via a seal member; and
said material supply section further has a material discharge passage for discharging the material gas and decomposition products thereof from the space, said material discharge passage being coupled to the space via a seal member.

29. The layer forming apparatus according to claim 28, wherein said material supply section and said material discharge passage are provided as two passages which are concentrically arranged.

30. The layer forming apparatus according to claim 20, wherein:
said material supply section comprises a material supply member having a coating film of the metal-organic material thereon;
said material supply member faces the workpiece; and
a distance between the workpiece and said material supply member is not more than 3 mm.

31. The layer forming apparatus according to claim 30, wherein the coating film of the metal-organic material on said material supply member is heated and vaporized by convection heat or radiant heat from the surface of the workpiece heated.

32. The layer forming apparatus according to claim 20, wherein the metal-organic material contains at least one of cobalt, tungsten, platinum, aluminum, copper, molybdenum, manganese, and silicon.

33. The layer forming apparatus according to claim 20 wherein the workpiece is a semiconductor wafer, a ceramic, a resin, or a metal.

34. The layer forming apparatus according to claim 20, wherein the workpiece has thereon at least one layer composed of a material selected from the group consisting of semiconductor, ceramic, resin, Ru, RuO₂, Cu, Ta, TaN, Ti, TiN, Si, SiO₂, low-k material, Co, P, CoP, CoWP, W, WSiC, WC, Ni, and Al.

35. A workpiece processing apparatus comprising:
a layer forming apparatus according to any one of claims 20 to 31; and
a wet processing unit for performing a wet process on a workpiece having a metal layer or a metal compound layer formed by said layer forming apparatus.

36. The workpiece processing apparatus according to claim 35, wherein said wet processing unit comprises at least one of an electroplating unit, an electroless plating unit, a chemical mechanical polishing unit, an electrolytic etching unit, an electrolytic polishing unit, and a cleaning unit.

37. A workpiece processing apparatus comprising:
a layer forming apparatus according to any one of claims 20 to 31; and
a dry processing unit for performing a dry process on a workpiece having a metal layer or a metal compound layer formed by said layer forming apparatus.

38. The workpiece processing apparatus according to claim 37, wherein said dry processing unit comprises at least one of an annealing unit, a CVD unit, and a gas etching unit.
